(19) United States
(12) Patent Application Publication
(10) Pub. No.: US 2010/0022091 A1
(43) Pub. Date: Jan. 28, 2010

(54) METHOD FOR PLASMA ETCHING POROUS LOW-K DIELECTRIC LAYERS

(76) Inventors: SIYI LI, Fremont, CA (US); Qingjun Zhou, Sunnyvale, CA (US); Ryan Patz, Albany, NY (US); Yifeng Zhou, Sunnyvale, CA (US); Jeremiah Pender, San Jose, CA (US); Michael D. Armacost, San Jose, CA (US)

Correspondence Address: APPLIED MATERIALS/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/180,367

(22) Filed: Jul. 25, 2008

(51) Int. Cl. H01L 21/306

(52) U.S. Cl. 438/706; 156/345.26; 257/E21.215; 257/E21.218

(57) ABSTRACT

Described herein are methods and apparatuses for etching low-k dielectric layers to form various interconnect structures. In one embodiment, the method includes forming an opening in a resist layer. The method further includes etching a porous low-k dielectric layer with a process gas mixture that includes a fluorocarbon gas and a carbon dioxide (CO₂) gas to form vias. The fluorocarbon gas may be C₄F₆ gas. A ratio of a flow rate of the C₄F₆ gas to a flow rate of the CO₂ gas can vary from approximately 1:2 to 1:10. In another embodiment, the porous low-k dielectric layer is etched with a process gas mixture that includes a fluorocarbon gas and an argon gas with no CHF₃ gas to form trenches aligned with the vias in an integrated dual-damascene structure. The fluorocarbon gas may be CF₄ gas.

### TECHNICAL FIELD

Embodiments of the present invention relate to etching porous low dielectric constant (low-k) layers.

### BACKGROUND

As semiconductor manufacturing technology advances to smaller and smaller feature sizes, porous low dielectric constant (low-k) integration with Copper interconnect technology has been widely evaluated. Interconnect delay becomes a significant performance barrier for high-speed signal conduction. The use of dielectric materials with a lower dielectric constant can significantly improve performance measures by reducing signal propagation time delay, cross talk, and power consumption in semiconductor devices having a multilevel interconnect architecture. The most-used dielectric material for semiconductor fabrication has been silicon oxide (SiO₂), which has a dielectric constant in the range of k=3.9 to 4.5, depending on its method of formation. Dielectric materials with k less than 3.9 are classified as low-k dielectrics. Some low-k dielectrics are organosilicates formed by doping silicon oxide with carbon-containing compounds.

Integration of porous low-k layers has exerted significant challenges. First, a barrier metal (e.g., Tantalum Nitride, Tantalum) or even Copper penetration into the dielectric results in increased leakage and capacitance. Second, plasma processing during various well-known etching and/or stripping operations causes damage to porous low-k dielectric layers having highly connected pore structures and high carbon concentration. The pore structures potentially induce non-uniform polymer deposition during plasma processing. This leads to striation issues and increased plasma damage based on losing CH₃ groups from the low-k film. Also, the high carbon concentration increases micro-trenching near a perimeter of a via or trench bottom surface and also leads to having a rough etch front as illustrated in FIG. 4A. Additionally, the pore structures and high carbon concentration cause micro-loading issues (e.g., etch rate differences between dense and non-dense features).

### SUMMARY

Described herein are methods and apparatuses for etching low-k dielectric layers to form various interconnect structures. In one embodiment, the method includes forming an opening in a resist layer. The method further includes etching a porous low-k dielectric layer with a process gas mixture that includes a fluorocarbon gas and a carbon dioxide (CO₂) gas to form vias. The fluorocarbon gas may be C₄F₆ gas. A ratio of a flow rate of the C₄F₆ gas to a flow rate of the CO₂ gas can vary from approximately 1:2 to 1:10.

In another embodiment, an opening in another resist layer is formed. The porous low-k dielectric layer is etched with a process gas mixture that includes a fluorocarbon gas and an argon gas with no CHF₃ gas to form trenches aligned with the vias in an integrated dual-damascene structure. The fluorocarbon gas may be CF₄ gas.

### BRIEF DESCRIPTION OF THE DRAWINGS

Embodiments of the present invention are illustrated by way of example, and not by way of limitation, in the figures of the accompanying drawings and in which:

FIG. 1 illustrates one embodiment of a method for etching a low-k dielectric layer in an interconnect structure in accordance with one embodiment;

FIG. 2A illustrates a cross-sectional view of an interconnect structure fabricated to form a via in accordance with one embodiment;

FIG. 2B illustrates a cross-sectional view of an interconnect structure fabricated to form a via in accordance with another embodiment;

FIG. 2C illustrates a cross-sectional view of an interconnect structure fabricated to form a via in accordance with another embodiment;

FIG. 3A illustrates a cross-sectional view of an interconnect structure fabricated to form a trench in accordance with another embodiment;

FIG. 3B illustrates a cross-sectional view of an interconnect structure fabricated to form a trench in accordance with another embodiment;

FIG. 3C illustrates a cross-sectional view of an interconnect structure fabricated to form a trench in accordance with another embodiment;

FIG. 3D illustrates a cross-sectional view of an interconnect structure fabricated to form a trench in accordance with another embodiment;

FIG. 3E illustrates a cross-sectional view of a dual-damascene interconnect structure fabricated in accordance with one embodiment;

FIG. 3F illustrates a cross-sectional view of a dual-damascene interconnect structure fabricated in accordance with another embodiment;

FIG. 3G illustrates a cross-sectional view of a dual-damascene interconnect structure fabricated in accordance with another embodiment;

FIG. 3H illustrates a cross-sectional view of a dual-damascene interconnect structure fabricated in accordance with another embodiment;

FIG. 4A illustrates a cross-sectional view of a structure having a rough etch front in accordance with a prior approach;

FIG. 4B illustrates a cross-sectional view of a structure having a smooth etch front in accordance with one embodiment;

FIG. 4C illustrates a cross-sectional view of a structure having a minimal RIE lag in accordance with one embodiment; and

FIG. 5 is a cross-sectional view of a substrate processing chamber in accordance with one embodiment.

### DETAILED DESCRIPTION

Described herein are exemplary methods for etching low-k dielectric layers to form dual-damascene interconnect structures having vias and trenches. In one embodiment, the method includes forming an opening in a resist layer disposed on a low-k dielectric layer. The method further includes etching the low-k dielectric layer with a process gas mixture that includes a fluorocarbon gas and a carbon dioxide (CO₂) gas. In an embodiment, the fluorocarbon gas may be C₄F₆ gas. A ratio of a flow rate of the C₄F₆ gas to a flow rate of the CO₂ gas can vary from approximately 1:2 to 1:10.

In another embodiment, the low-k dielectric layer is etched with a process gas mixture that includes a fluorocarbon gas and an inert gas such as argon, helium, or xenon gas with no CHF₃ gas. In an embodiment, the fluorocarbon gas may be CF₄ gas. A ratio of a flow rate of the CF₄ gas to a flow rate of the inert gas is approximately equal to 1:1. The etch process gas mixtures described herein can etch a porous low-k dielectric layer to form vias and/or trenches in via then trench process flows as well as trench then via process flows. The process gas mixture that includes fluorocarbon gas and carbon dioxide (CO₂) gas can be used to etch vias with improved striation/line edge roughness, micro-trenching, micro-loading, and profile control compared to prior approaches that use process mixtures with N₂ gas.

The process gas mixture that includes fluorocarbon gas and an inert gas with no CHF₃ gas improves the etch front (e.g., surface roughness) significantly compared to a fluorocarbon/CHF₃ gas chemistry. Also, this new etch process has improved etch micro-loading and profile control. These novel process gas mixtures can be used independently in etching dielectric layers or in combination as a part of an integrated dual damascene process flow.

The following description provides details of manufacturing machines that process substrates and/or wafers to manufacture devices (e.g., electronic devices, semiconductors, substrates, liquid crystal displays, reticles, micro-electro-mechanical systems (MEMS)). Manufacturing such devices generally require dozens of manufacturing steps involving different types of manufacturing processes. For example, etching, sputtering, and chemical vapor deposition are three different types of processes, each of which is performed on different chambers or in the same chamber of a machine.

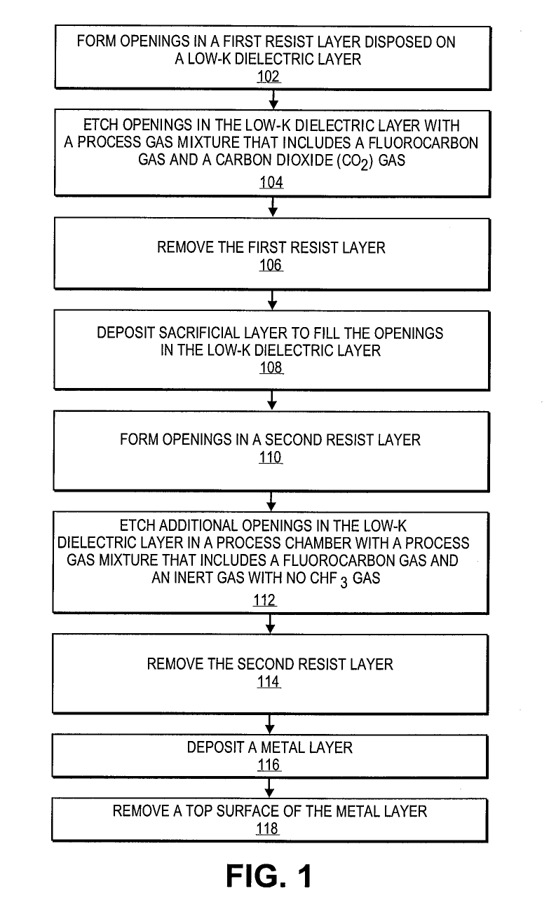

FIG. 1 illustrates one embodiment of a method for etching a porous low-k dielectric layer to form an interconnect structure. The method includes forming openings in a first resist layer (e.g., photoresist, anti-reflective coating (ARC)) with photolithography operations (at block 102). The first resist layer may be disposed on an optional hard mask layer which is disposed on the porous low-k dielectric layer. An opening in the optional hard mask layer may occur by wet or dry etching the hard mask layer (e.g., low temperature oxide, organic layer, TEOS). Next, the method includes etching openings in the porous low-k dielectric layer with a process gas mixture that includes a fluorocarbon gas and a carbon dioxide (CO₂) gas at block 104. In one embodiment, the fluorocarbon gas is C₄F₆ gas. A ratio of a flow rate of the C₄F₆ gas to a flow rate of the CO₂ gas can vary from approximately 1:2 to 1:10. A similar or different etch chemistry can be used for etching the optional hard mask layer. In one embodiment, the porous low-k dielectric layer is etched to form vias above an etch stop layer disposed on a metal layer. The etch stop layer (e.g., SiC based film, SiCN based film) is part of an interconnect structure that prevents previously and/or subsequently deposited metal layers (e.g., aluminum copper, copper) from diffusing into other processing layers.

Next, the method includes removing the first resist layer at block 106. Next, the method includes depositing a sacrificial layer (e.g., organic layer, low temperature oxide, TEOS) to fill the openings in the low-k dielectric layer (e.g., vias) at block 108. Next, the method includes forming openings in a second resist layer with standard semiconductor processing operations at block 110. Then, the method includes etching additional openings in the porous low-k dielectric layer in a process chamber with a process gas mixture that includes a fluorocarbon gas and an inert gas (e.g., argon, helium, xenon) with no CHF₃ gas at block 112. In one embodiment, the fluorocarbon gas is CF₄ gas and the inert gas is argon gas. A ratio of a flow rate of the CF₄ gas to a flow rate of the argon gas is approximately equal to 1:1. In an embodiment, the porous low-k dielectric layer is etched to form additional openings (e.g., trenches) aligned above the initial openings (e.g., vias) that contact the etch stop layer. Then, the method includes removing the second resist layer at block 114. Then, the method includes depositing a metal layer at block 116. This deposition may include depositing a liner layer prior to depositing or plating the metal layer onto the interconnect structure. Finally, the method includes removing a top surface of the metal layer at block 118.

In one embodiment, the metal layer is etched with a chemical-mechanical planarization or chemical-mechanical polishing (CMP) process. This process is used in semiconductor fabrication for planarizing the top surface of an in-process semiconductor wafer or other substrate. In another embodiment, other conventional semiconductor processing occurs in order to etch the metal layer such as a blanket unmasked plasma etch or a masked plasma etch or a combination of conventional semiconductor processing.

The operations of exemplary methods described in the present invention can be performed in a different order, sequence, and/or have more or less operations than described. For example, in certain embodiments, the interconnect structure is formed by etching the trenches prior to etching the vias. In another embodiment, a trench etch is performed without a via etch. In another embodiment, a via etch is performed without a trench etch.

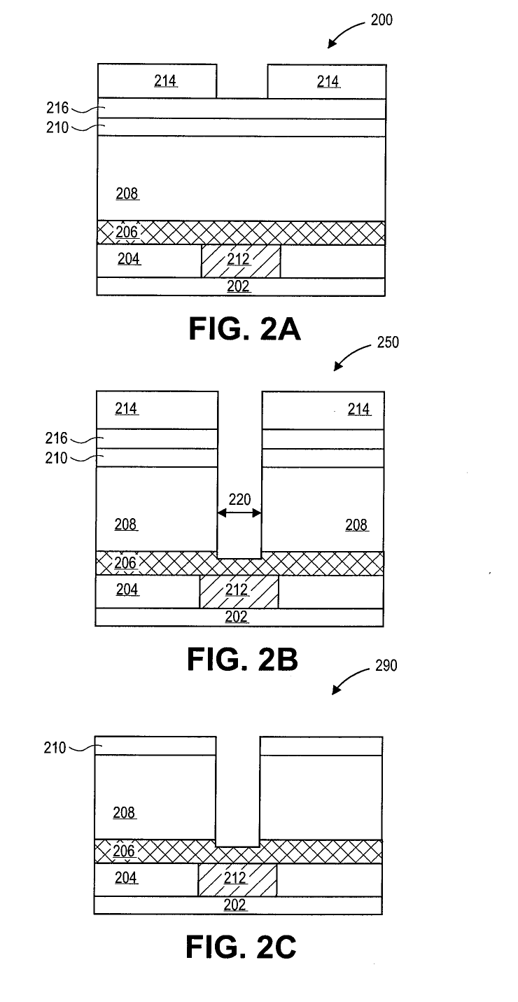

FIG. 2A illustrates a cross-sectional view of an interconnect structure 200 fabricated to form a via in accordance with one embodiment. The interconnect structure 200 includes a substrate 202, a dielectric layer 204 (e.g., thermal oxide, low temperature oxide, TEOS, doped oxide, etc), a metal layer 212 (Copper, Aluminum Copper), an etch stop layer 206 (e.g., non-conductive material, SiC based film, SiCN based film), a porous low-k dielectric layer 208, a masking layer 210 (e.g., low temperature oxide, organic layer, TEOS) to be used as a hard mask during the low-k dielectric etch, an optional anti-reflective coating (ARC) layer 216 to minimize the reflectance of underlying layers, and a resist layer 214. The masking layer 210 may have a thickness of 20 to 100 nanometers (nm). In some embodiments, the low-k dielectric layer 208 has a dielectric constant less than 2.3, a porosity greater than twenty percent, contains greater than ten percent carbon, and has a thickness of about 1000 Angstroms to about 10000 Angstroms. The porous low-k dielectric layer has a density and pores of a certain size (e.g., about 5 to 20 Angstroms). For example, the porous low-k dielectric layer can be a pyrogenic film, a carbon doped oxide, or other type of dielectric layer having a low or ultra low-k. The resist layer 214 may be a photosensitive photoresist layer that is blanket coated or deposited across the interconnect structure, masked, exposed to a light source, and developed to form via openings in accordance with standard photolithography operations.

FIG. 2B illustrates a cross-sectional view of an interconnect structure 250 fabricated to form a via in accordance with another embodiment. The interconnect structure 250 of FIG. 2B illustrates the interconnect structure 200 of FIG. 2A after a via etch that results in the formation of the via 220. The etching of the ARC layer 216 and masking layer 210 may occur by etching dielectric and/or organic layers (e.g., low temperature oxide, organic layer, ARC layer, TEOS). In one embodiment, the porous low-k dielectric layer 208 is etched until reaching the etch stop layer 206 in a process chamber with a process gas mixture that includes a fluorocarbon gas and a carbon dioxide (CO₂) gas. For example, the fluorocarbon gas may include at least one fluorocarbon containing gas such as but not limited to C₄F₆ gas, C₄F₈ gas, CF₄ gas, and CHF₃ gas. For an etch process chemistry with C₄F₆ gas, a ratio of a flow rate of the C₄F₆ gas to a flow rate of the CO₂ gas can vary from approximately 1:2 to 1:10. In some embodiments, the process gas mixture may further include argon gas with no N₂ gas. The N₂ gas causes damage to the porous low-k dielectric layer 208 by depleting the Carbon in the layer 208. This leads to narrow process windows due to striation/line edge roughness and micro-trenching. Replacing N₂ gas with CO₂ gas in the porous low-k main etch or over etch significantly improves striation issues (e.g., ridges or linear marks in the etch surface and sidewall profile) and process control windows while being selective to the resist layer. Additionally, this new etch process with no N₂ gas has improved micro-loading and profile control. The flow rate of the argon gas can be ten to one hundred times greater than a flow rate of the C₄F₆ gas. In a specific embodiment, the etch includes the following process parameters:

5-30 sccm C₄F₆; 20-100 sccm CO₂; 100-1000 sccm Argon;

10-50 mTorr;

a chamber temperature of 10-60 degrees Celsuis (C.); and

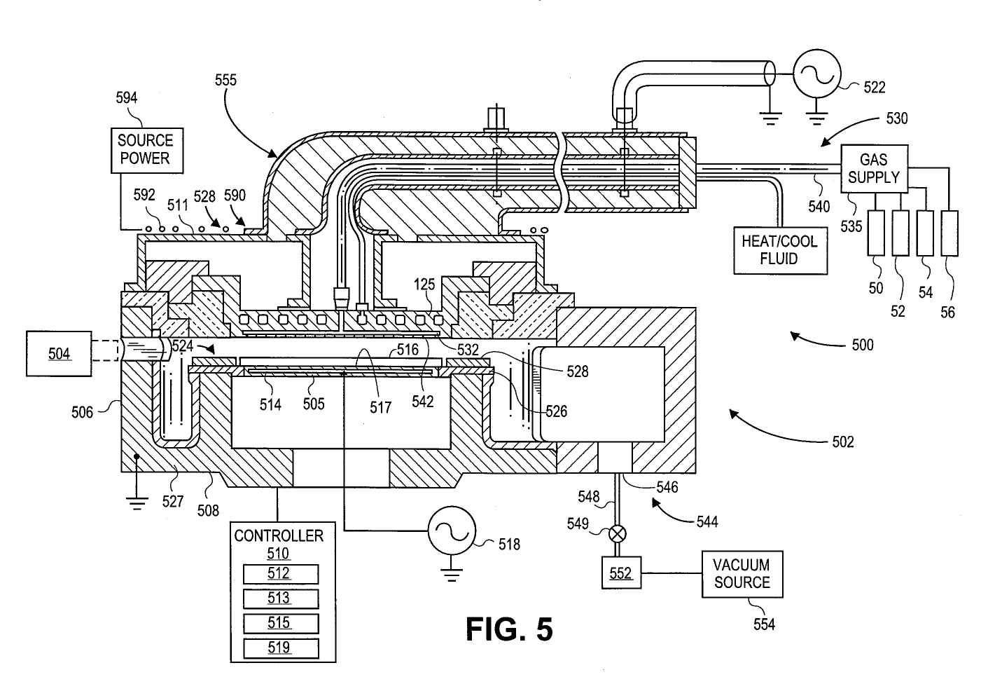

a source power up to 2000 watts, a total bias power of 1000-3000 watts with a RF bias frequency of 2 and/or 13 MHz in a plasma etch chamber, like Applied Materials' Enabler described in conjunction with FIG. 5.

The argon flow rate is used for ion directionality control and residency of ions in the plasma (e.g., 1-50 milliseconds) for a given pressure.

In other embodiments, the process gas mixture includes, in addition to the fluorocarbon gas and argon gas, a N₂ gas with a greater flow rate of N₂ gas than a flow rate of argon gas. The N₂ gas flow rate can be used for ion directionality control and profile control.

The process gas mixture having fluorocarbon gas and CO₂ gas, can also be used with other inert gases, such as helium, xenon, or even with N₂ gas or O₂ gas. The process gas mixture that includes a fluorocarbon gas and a carbon dioxide (CO₂) gas and potentially other variations can be used to etch any porous low-k dielectric layer to form vias, trenches, or other structures. This process gas mixture can be adjusted during main etch and over etch operations for more or less polymer build up. For example, increasing the ratio of C₄F₆/CO₂ gas increases the polymer which is useful for stopping the etch during an over etch operation.

FIG. 2C illustrates a cross-sectional view of an interconnect structure 290 fabricated to form a via in accordance with another embodiment. The interconnect structure 290 of FIG. 2C illustrates the interconnect structure 250 of FIG. 2B after the resist layer 214 and ARC layer 216 are removed with a wet strip or plasma strip/ash operation.

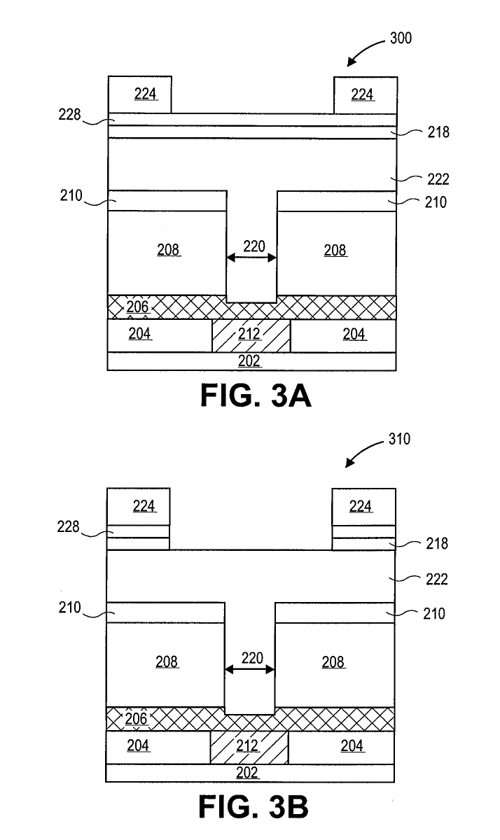

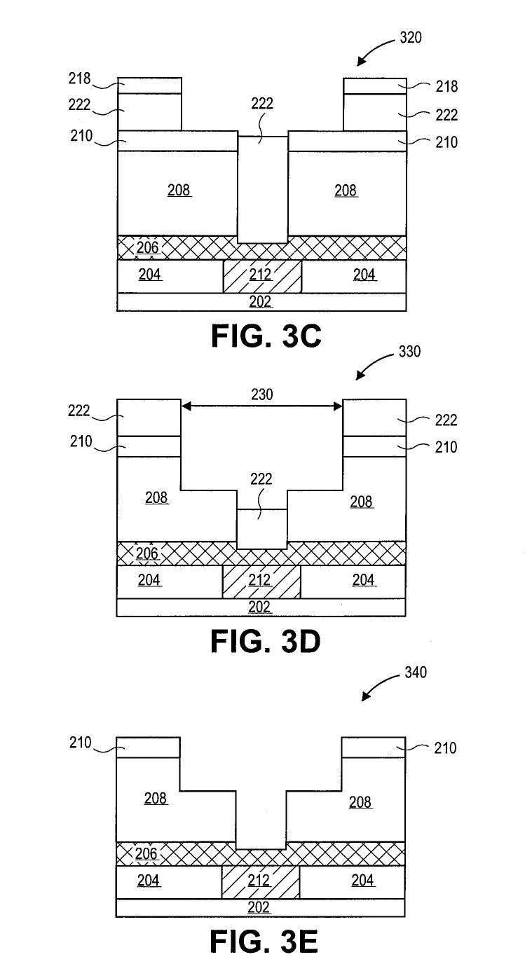

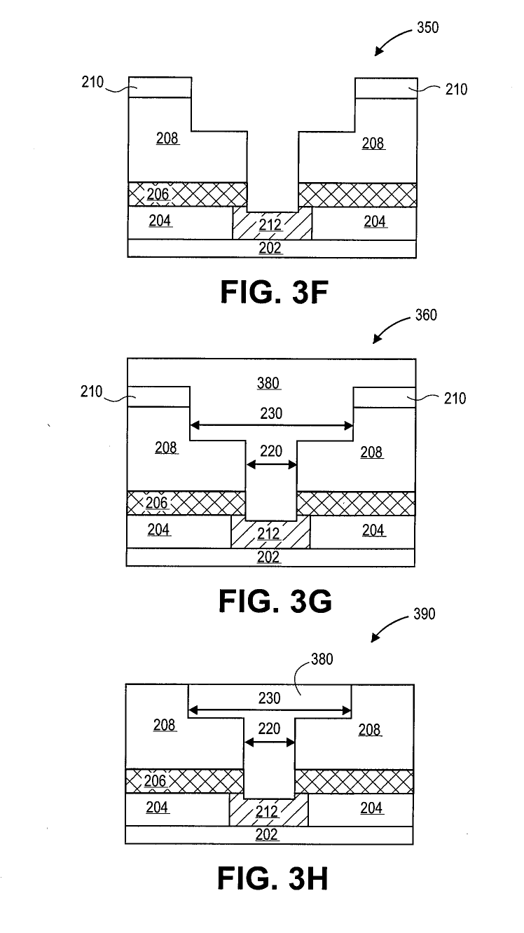

FIG. 3A illustrates a cross-sectional view of an interconnect structure 300 fabricated to form a trench in accordance with another embodiment. The interconnect structure 300 includes a sacrificial light absorbing layer 222, an optional oxide layer 218 (e.g., LTO), an optional ARC layer 228, and a resist layer 224 in addition to the layers illustrated in interconnect structure 290 of FIG. 2C. The interconnect structure 300 can also be formed independently as a trench etch without the via etch operations illustrated in FIGS. 2A-2C. The sacrificial layer 222 may include an organic sacrificial layer (e.g., ARC, spin on glass (SOG) such as phosphosilicates or siloxanes) and zero or more dielectric layers. The sacrificial layer fills the via 220 and planarizes variations in the film stack thickness across the substrate 202. The resist layer 224 is patterned with a trench mask, exposed to a light source, and the exposed or unexposed portions of the photoresist are dissolved with a photoresist developer to form trench openings in the resist layer 224.

FIG. 3B illustrates a cross-sectional view of an interconnect structure 310 fabricated to form a trench in accordance with another embodiment. The interconnect structure 310 of FIG. 3B illustrates the interconnect structure 300 of FIG. 3A after a hard mask etch of the optional ARC layer 228 and the optional oxide layer 218.

FIG. 3C illustrates a cross-sectional view of an interconnect structure 320 fabricated to form a trench in accordance with another embodiment. The interconnect structure 320 of FIG. 3C illustrates the interconnect structure 310 of FIG. 3B after the sacrificial layer 222 is partially etched to form a trench opening. The resist layer 224 and ARC layer 228 are also removed during this etch with the oxide layer 218 and masking layer 210 being etch stop layers.

FIG. 3D illustrates a cross-sectional view of an interconnect structure 330 fabricated to form a trench in accordance with another embodiment. The interconnect structure 330 of FIG. 3D illustrates the interconnect structure 320 of FIG. 3C after a trench etch of the masking layer 210, the low-k dielectric layer 208, and the sacrificial layer 222 that result in the formation of the trench 230. The oxide layer 218 which acts as a masking layer is also etched during the trench etch.

In one embodiment, the porous low-k dielectric layer 208 is etched in a process chamber with a process gas mixture that includes a fluorocarbon gas and an inert gas such as argon, helium, or xenon gas with no CHF₃ gas. The replacement of CHF₃ gas with argon gas or other inert gases (e.g., helium, xenon) improves the etch front significantly compared to a fluorocarbon/CHF₃ gas chemistry. Also, this new etch process has improved etch micro-loading and profile control. The fluorocarbon gas may not include C₄F₆ gas nor CH₂F₂ gas. In one embodiment, the fluorocarbon gas is CF₄ gas and a ratio of a flow rate of the CF₄ gas to a flow rate of the argon gas is approximately equal to 1:1. In a specific embodiment, the etch includes the following process parameters:

50-400 sccm CF₄; 50-400 sccm argon;

50-200 mTorr;

a chamber temperature of 10-60 degrees Celsuis (C.); and

a source power up to 2000 watts, a total bias power of 1000-3000 watts with a RF bias frequency of 2 and/or 13 MHz in a plasma etch chamber, like Applied Materials' Enabler described in conjunction with FIG. 5.

FIG. 3E illustrates a cross-sectional view of a dual-damascene interconnect structure 340 fabricated in accordance with another embodiment. The interconnect structure 340 of FIG. 3E illustrates the interconnect structure 330 of FIG. 3D after a plasma strip or ashing of the sacrificial layer 222 to form the trench 230 and the via 220. The exposed surface of the etch stop layer 206 is partially etched during the plasma strip or ashing.

FIG. 3F illustrates a cross-sectional view of a dual-damascene interconnect structure 350 fabricated in accordance with another embodiment. The interconnect structure 350 of FIG. 3F illustrates the interconnect structure 340 of FIG. 3E after the exposed surface of the etch stop layer 206 is etched until reaching the metal layer 212. A post etch operation is also performed to clean the exposed surfaces of the interconnect structure 350.

FIG. 3G illustrates a cross-sectional view of a dual-damascene interconnect structure 360 fabricated in accordance with another embodiment. In one embodiment, a metal layer 380 (e.g., copper, aluminum copper) is blanket deposited or plated onto the interconnect structure 360. The vias and trenches are filled with the metal layer 380. A barrier metal layer (e.g., Ti, TiN, Ta, TaN), not shown, may optionally be deposited prior to the deposition of the metal layer 380. The barrier metal layer prevents the diffusion of metal from the metal layer into other materials such as the low-k dielectric layer.

FIG. 3H illustrates a cross-sectional view of an interconnect structure 390 fabricated in accordance with another embodiment. In one embodiment, a top surface of the metal layer 380 is removed using standard semiconductor processing operations such as etching. In an embodiment, a chemical-mechanical planarization process etches a top surface of the metal layer 380 disposed on the interconnect structure 390. The metal layer 380 and masking layer 210 are etched until reaching the porous dielectric layer 208 resulting in the interconnect structure 390. The masking layer 210 having a higher dielectric constant in comparison to the porous dielectric layer 208 may be completely removed in order to minimize the dielectric constant of the interconnect structure 390. In some embodiments, the planarization process stops etching upon reaching the masking layer 210 thus leaving a portion of the masking layer 210. The at least one via 220 and at least one trench 230 have been filled with the metal layer 380 (e.g., Cu plating, AlCu deposition).

In one embodiment, the interconnect structures described herein illustrate a dual-damascene process having at least one via 220 and at least one trench 230 formed from semiconductor deposition, lithography, etch, strip, and planarization operations. Dual-damascene forms studs and interconnects with one metallization operation. The dual-damascene process increases the density, performance, and reliability in a fully integrated wiring technology. In another embodiment, the interconnect structure 300 is a single damascene structure or other structure that forms an opening in a porous dielectric layer.

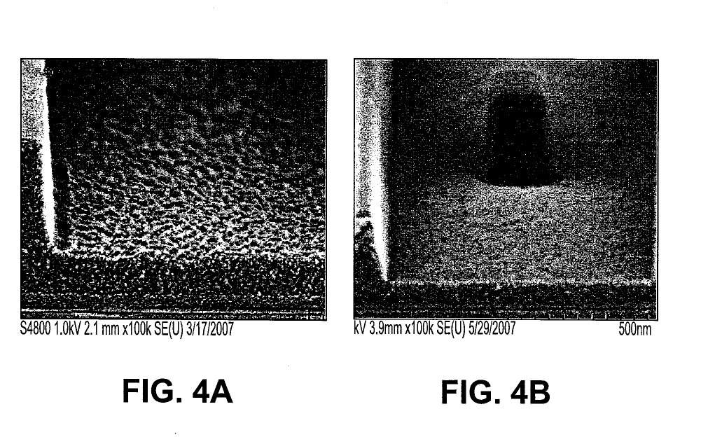

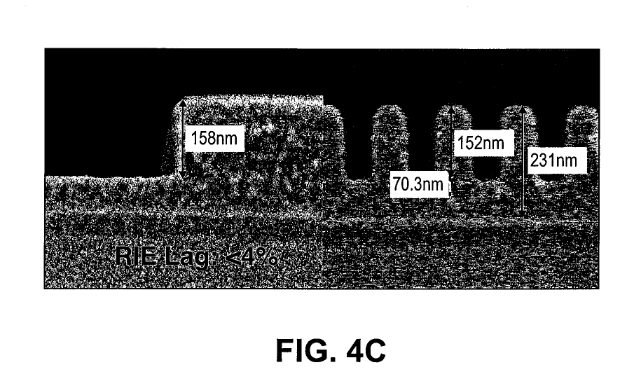

FIG. 4A illustrates a cross-sectional view of a structure having a rough etch front fabricated in accordance with a prior approach. In this case, the porous low-k dielectric layer was etched with a fluorocarbon/CHF₃ gas chemistry.

FIG. 4B illustrates a cross-sectional view of a structure having a smooth etch front fabricated in accordance with one embodiment. For the structure, the porous low-k dielectric layer was etched with a fluorocarbon/argon gas chemistry with no CHF₃ gas. The feature etched in FIG. 4B has a smooth surface with minimal surface roughness in comparison to the feature illustrated in FIG. 4A because the CHF₃ gas was replaced with argon gas for process gas mixture used for FIG. 4B.

FIG. 4C illustrates a cross-sectional view of a structure having a minimal reactive ion etch (RIE) lag fabricated in accordance with one embodiment. A RIE lag is defined to be the percent difference in an etch depth for a wide non-dense feature minus an etch depth for a dense feature divided by the etch depth for the non-dense feature. The structure in FIG. 4C has a RIE lag of merely 4% and was etched with a fluorocarbon/Argon gas chemistry with no CHF₃ gas. The non-dense feature on the left of this figure has an etch depth of 158 nanometers (nm) and the dense feature on the right has an etch depth of 152 nm. Optimizing the ratio of the flow rate of the CF₄ gas to the flow rate of the argon gas results in a smooth etch front and minimal reactive ion etch (RIE) lag as illustrated in FIGS. 4B and 4C. The process gas mixture that includes a fluorocarbon gas and an argon gas or other inert gas with no CHF₃ gas can be used to etch any porous low-k dielectric layer to form vias, trenches, or other structures.

The interconnect structures discussed above can be fabricating with the apparatus 500 described herein which is suitable for processing substrates 517 such as semiconductor substrates 202, and may be adapted by those of ordinary skill to process other substrates 517 such as flat panel displays, polymer panels or other electrical circuit receiving structures. Thus, the apparatus 500 should not be used to limit the scope of the invention, nor its equivalents, to the exemplary embodiments provided herein.

An embodiment of an apparatus 500 suitable for processing substrates 517 according to the processes described herein, is shown in FIG. 5. FIG. 5 provides a cross-sectional view of a substrate processing apparatus 500 having an antenna and first and second process electrodes. The substrate processing chamber 502 of the apparatus 500 is mounted on a platform (not shown) that provides electrical, plumbing, and other support functions. The platform typically supports a load lock chamber and a substrate transfer chamber. The load lock chamber receives a cassette of substrates 517 to be processed. The substrate transfer chamber contains a substrate transfer mechanism 504 such as a robot including a substrate blade, to transfer substrates 517 from the cassette to and from the different chambers on the platform, for processing. The chambers are interconnected in a vacuum environment so that processing of the substrates 517 may proceed uninterrupted within the apparatus 500, thereby reducing contamination of the substrates 517, that may otherwise occur when transferring the substrates 517 between separate chambers for different process stages.

The substrate processing apparatus 500 includes a processing chamber 502 including enclosure walls that include sidewalls 506, a bottom 508, and a ceiling 511 disposed thereon; the enclosure walls forming an isolated processing environment. The sidewalls 506 of the chamber 502 may be isolated from the processing environment in the chamber 502 by using magnetic isolation. Alternatively, the sidewalls 506 may have a dielectric coating thereon, or an annular dielectric insert or removable liner may be disposed adjacent the sidewalls 506.

Each chamber 502 further includes a substrate support 505 to support a substrate 517 in the chamber 502. The substrate support 505 is generally formed from materials such as stainless steel, aluminum, or other materials that are electrically conductive and adapted to withstand substrate processing. The substrate support 505 typically includes an electrostatic chuck including a dielectric body that at least partially covers an electrode 514 and which includes a substrate receiving surface 116. The electrode 514 may also serve as a process electrode. The electrode 514 may be capable of generating an electrostatic charge for electrostatically holding the substrate 517 to the electrostatic chuck. For example, the electrode 514 may be made, for example, from a metal such as tungsten, tantalum or molybdenum. A chucking voltage supply applies a DC chucking voltage to the electrode 514. To electrically bias plasma toward and away from the substrate support 505, an electrical bias 522 and an electrical bias 518 may be coupled to the electrode 514.

A ring assembly 524 surrounds an outer edge of the substrate support 505. The ring assembly includes a deposition ring 526 made of a dielectric such as quartz, and a cover ring 528. The deposition ring 526 is supported on the grounded chamber body 527 and the cover ring 528 is supported by the deposition ring 526.

In operation, process gas is introduced into the chamber 502 through a gas delivery system 530 that includes a gas distributor 532, a process gas supply 535 including a source of a first fluorocarbon process gas 50, a source of a second fluorocarbon process gas 52, a source of a CO₂ process gas 54, and a source of one or more inert gases 56. Each source has respective conduits each having a gas control valve, such as a mass flow controller, to pass a set flow rate of the respective gas therethrough. The conduits feed the gases to a mixing manifold in which the gases are mixed to form a desired process gas composition. The mixing manifold passes the mixed process gas through a metal gas line 540 to the gas distributor 532 having gas outlets 542 in the chamber 502.

Spent process gas and byproducts are exhausted from the chamber 502 through a gas exhaust 544. The exhaust 544 includes one or more exhaust ports 546 that receive spent process gas and pass the spent gas to an exhaust conduit 548 in which there is a throttle valve 549 to control the pressure of the gas in the chamber 502. During operation, the chamber 502 is typically at a pressure between 10 and 200 mTorr. The exhaust conduit feeds one or more exhaust pumps 552. The exhaust pump 552 is in fluid communication with a vacuum source 554 through a pumping valve (not shown). It is contemplated that the exhaust pump 552 may be a separate body coupled to the chamber 502 (as shown). In a gas purge or vacuum process, the pumping valve couples the vacuum source to the port 546 at a pressure desired for semiconductor processing while allowing for rapid removal of waste gases using a single vacuum source 554.

The process gas is energized to process the substrate 517 by a gas energizer 588 that couples energy to the process gas in the chamber 502. The gas energizer 588 includes an antenna 590 adjacent to the ceiling 511. The antenna 590 may be configured with RF coils 592 coupled to a source RF power generator 594 through a matching network (not shown), to inductively couple RF energy into the chamber 502. A capacitive source may also be used by creating a capacitively-coupled plasma.

The gas energizer 588 also includes the electrode disposed within the substrate support 514 and the overhead electrode 525 spaced apart from the receiving surface 516 of the substrate support 505. Both the electrode 514 within the substrate support 505 and the overhead electrode 525 are each coupled to bias RF power generators 522 and 518 through an impedance matching network (not shown) and an isolation capacitor (not shown). The overhead electrode 525 including the dielectric ceiling serves as an induction field transmitting window that provides a low impedance to an RF induction field transmitted by the antenna 590 above the ceiling 511. Suitable dielectric materials that can be employed include materials such as aluminum oxide or silicon dioxide. The electrodes 514, 525 are electrically biased relative to one another by electrode voltage supply (not shown) that includes an AC voltage supply for providing an RF bias voltage. The RF bias voltage may include frequencies of about 50 kHz to about 60 MHz, and the power level of the RF bias current is typically from about 50 to about 3000 Watts. The RF source bias voltage may include frequencies of about 5 MHz to about 250 MHz, and the power level of the RF bias current is typically from about 50 to about 3000 Watts.

The chamber 502 may be operated by a controller 510 including a computer that sends instructions via a hardware interface to operate the chamber components, for example, the substrate support 505, the gas distributor 532, the gas energizer 588 and the gas exhaust 544. The process conditions and parameters measured by the different detectors in the chamber 502 are sent as feedback signals by control devices such as the gas flow control valves, pressure monitor (not shown), throttle valve 549, and other such devices, and are transmitted as electrical signals to the controller 510. Although, the controller 510 is illustrated by way of an exemplary single controller device to simplify the description of present invention, it should be understood that the controller 510 may be a plurality of controller devices that may be connected to one another or a plurality of controller devices that may be connected to different components of the chamber 502. Thus, the present invention should not be limited to the illustrative and exemplary embodiments described herein.

The controller 510 includes electronic hardware including electrical circuitry including integrated circuits that are suitable for operating the chamber 502 and its peripheral components. Generally, the controller 510 is adapted to accept data input, run algorithms, produce useful output signals, detect data signals from the detectors and other chamber components, and to monitor or control the process conditions in the chamber 502. For example, the controller 510 may include a computer including (i) a central processing unit (CPU) 512, such as for example, a conventional microprocessor, that is coupled to a memory 513 that includes a removable storage medium, such as for example a CD or floppy drive, a non-removable storage medium, such as for example a hard drive or ROM, and RAM; (ii) application specific integrated circuits (ASICs) that are designed and preprogrammed for particular tasks, such as retrieval of data and other information from the chamber 502, or operation of particular chamber components; and (iii) interface boards that are used in specific signal processing tasks, including, for example, analog and digital input and output boards, communication interface boards and motor controller boards. The controller interface boards, may for example, process a signal from a process monitor and provide a data signal to the CPU. The computer also has support circuitry that include for example, co-processors, clock circuits, cache, power supplies and other well known components that are in communication with the CPU. The RAM can be used to store the software implementation of the present invention during process implementation. The instruction sets of code 515 of the present invention are typically stored in storage mediums and are recalled for temporary storage in RAM when being executed by the CPU.

In one embodiment, the controller 510 includes computer program instructions 515 that are readable by the computer and may be stored in the memory 513, for example on the non-removable storage medium or on the removable storage medium. The computer program instructions 515 generally includes process control software including program code including instructions to operate the chamber and its components, process monitoring software to monitor the processes being performed in the chamber 502, safety systems software, and other control software.

In some embodiments, the controller 510 is operatively coupled to the process chamber 502, the gas distributor 532, the gas energizer 588, and the gas exhaust 544. In a specific embodiment for a via etch, the controller 510 includes program code instructions 515 to operate the gas distributor to introduce into the chamber 502 a process gas mixture including the following:

5-30 sccm C₄F₆; 20-100 sccm CO₂; 100-1000 sccm argon;

10-50 mTorr chamber pressure;

a chamber temperature of 10-60 degrees Celsuis (C.); and

a source power up to 2000 watts, a total bias power of 1000-3000 watts with a RF bias frequency of 2 and/or 13 MHz in a plasma etch chamber, like Applied Materials' Enabler described in conjunction with FIG. 5.

The process gas mixture having fluorocarbon gas and CO₂ gas, can also be used with other inert gases, such as helium, xenon, or even with N₂ gas or O₂ gas for the via etch.

In a specific embodiment for a trench etch, the controller 510 includes the program code instructions 519 to operate the gas distributor to introduce into the chamber 502 a process gas mixture including the following:

50-400 sccm CF₄; 50-400 sccm argon;

50-200 mTorr chamber pressure;

a chamber temperature of 10-60 degrees Celsuis (C.); and

a source power up to 2000 watts, a total bias power of 1000-3000 watts with a RF bias frequency of 2 and/or 13 MHz in a plasma etch chamber, like Applied Materials' Enabler described in conjunction with FIG. 5.

In other embodiments for the trench etch, the argon gas is replaced with a different inert gas such as helium or xenon gas. In another embodiment, the instructions 515 or 519 includes both instructions for the via and trench etch as discussed above.

In the following description, numerous details are set forth. It will be apparent, however, to one skilled in the art, that the present invention may be practiced without these specific details. In some instances, well-known structures and devices are shown in block diagram form, rather than in detail, in order to avoid obscuring the present invention. It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

What is claimed is:

1. A method of etching a dielectric layer having a low dielectric constant (low-k) in a process chamber, comprising:
forming an opening in a resist layer disposed on the low-k dielectric layer; and
etching the low-k dielectric layer in the process chamber with a process gas mixture comprising a fluorocarbon gas and an inert gas with no CHF₃ gas.

2. The method of claim 1, wherein the low-k dielectric layer has a dielectric constant less than 2.3, a porosity greater than twenty percent, and contains greater than ten percent carbon.

3. The method of claim 1, wherein the fluorocarbon gas is CF₄ gas.

4. The method of claim 3, wherein the inert gas is argon gas.

5. The method of claim 4, wherein a ratio of a flow rate of the CF₄ gas to a flow rate of the argon gas is approximately equal to 1:1.

6. The method of claim 1, wherein the process gas mixture does not include C₄F₆ gas nor CH₂F₂ gas.

7. The method of claim 1, wherein the low-k dielectric layer has a thickness of 1000 Angstroms (A) to 10000 A.

8. A substrate processing apparatus comprising:
(a) a process chamber comprising:
(1) a substrate support comprising a substrate receiving surface to receive a substrate comprising a masking layer overlying a porous low dielectric constant (low-k) dielectric layer;
(2) a gas distributor to distribute a process gas mixture in the chamber;
(3) a gas energizer to energize the process gas mixture;
(b) a controller operatively coupled to the process chamber, the gas distributor, the gas energizer, and the gas exhaust, the controller comprising a program code to operate the gas distributor to introduce into the chamber the process gas mixture comprising a fluorocarbon gas and an inert gas with no CHF₃ gas to etch the porous low-k dielectric layer.

9. The substrate processing apparatus of claim 8 wherein the program code comprises instructions to operate the gas distributor to set a ratio of a flow rate of the fluorocarbon gas to a flow rate of the inert gas to approximately 1:1.

10. An apparatus according to claim 9 wherein the fluorocarbon gas is CF₄ gas and the inert gas is argon gas to etch the porous low-k dielectric layer to form trenches.

11. An apparatus according to claim 10 wherein the program code comprises instructions to operate the gas distributor to provide another process gas mixture comprising a fluorocarbon gas and CO₂ gas to etch the porous low-k dielectric layer to form vias.

12. The apparatus according to claim 11, wherein the fluorocarbon gas is C₄F₆ gas

13. A method of etching a porous dielectric layer having a low dielectric constant (low-k) in a process chamber, comprising:
forming an opening in a first resist layer; and
etching the porous low-k dielectric layer in the process chamber with a process gas mixture comprising a fluorocarbon gas and a CO₂ gas to form vias.

14. The method of claim 13, wherein the low-k dielectric layer has a dielectric constant less than 2.3, a porosity greater than twenty percent, and contains greater than ten percent carbon.

15. The method of claim 13, wherein the fluorocarbon gas is C₄F₆ gas.

16. The method of claim 15, wherein a range of a ratio of a flow rate of the C₄F₆ gas to a flow rate of the CO₂ gas is approximately 1:2 to 1:10.

17. The method of claim 15, wherein the process gas mixture further comprises argon gas and does not include N₂ gas with a flow rate of the argon gas being ten to hundred times greater than a flow rate of the C₄F₆ gas.

18. The method of claim 13, wherein the process gas mixture further comprises argon gas and N₂ gas with a greater flow rate of N₂ gas than flow rate of argon gas.

19. The method of claim 13, comprising:
forming an opening in a second resist layer; and
etching the porous low-k dielectric layer in the process chamber with another process gas mixture comprising a fluorocarbon gas and an inert gas with no CHF₃ gas to form trenches aligned with the vias in an integrated dual-damascene structure.

20. The method of claim 19, wherein the fluorocarbon gas is CF₄ gas and the inert gas is argon gas.

21. The method of claim 20, wherein a ratio of a flow rate of the CF₄ gas to a flow rate of the argon gas is approximately equal to 1:1.
